(19) United States
(12) Patent Application Publication
(10) Pub. No.: US 2025/0011960 A1
(43) Pub. Date: Jan. 9, 2025

(54) METHOD FOR MANUFACTURING FINE METAL MASK

(71) Applicant: GrapheneLab.Co.,Ltd, Hwaseong-si (KR)

(72) Inventors: Sang Min LEE, Yongin-si (KR); Young Duck KWON, Gwangmyeong-si (KR); Byong Wook YOO, Namyangju-si (KR); Ki Soo KIM, Seongnam-si (KR); Jong Taik MOON, Seongnam-si (KR); Seung Il MOON, Ansan-si (KR); Da Som HYUN, Osan-si (KR)

(21) Appl. No.: 18/889,099

(22) Filed: Sep. 18, 2024

Related U.S. Application Data
(63) Continuation of application No. PCT/KR2023/003832, filed on Mar. 23, 2023.

(30) Foreign Application Priority Data
Mar. 24, 2022 (KR) 10-2022-0036651

(51) Int. Cl. C25D 1/10; G03F 7/00

(52) U.S. Cl. CPC C25D 1/10; G03F 7/0005

(57) ABSTRACT

A method for manufacturing a fine metal mask includes the steps of a) patterning a plated resist on a substrate, b) forming a metal plated layer on the substrate exposed through the patterned plated resist, c) removing the patterned plated resist after step b), and d) separating the metal plated layer and the substrate. In step a), a cross-section of the plated resist is formed into a trapezoidal shape.

### CROSS-REFERENCE TO RELATED APPLICATIONS

The present application is a Continuation of International Application No. PCT/KR2023/003832 filed Mar. 23, 2023, which claims priority from Korean Application No. 10-2022-0036651 filed Mar. 24, 2022. The aforementioned applications are incorporated herein by reference in their entireties.

### TECHNICAL FIELD

The present disclosure relates generally to a method for manufacturing a fine metal mask. More particularly, the present disclosure relates to a method for manufacturing a fine metal mask (FMM) using electroforming among methods for manufacturing a metal mask for OLEDs.

### RELATED ART

Recently, research has been conducted on an electroforming method in manufacturing of thin plates. Electroforming is a method that involves immersing an anode and a cathode in an electrolyte, applying electricity, and depositing a thin metal plate on a surface of the cathode. It can be used to manufacture extremely thin plates and enables mass production.

Meanwhile, as a technology for forming pixels in an OLED manufacturing process, a fine metal mask (FMM) method is mainly used. In this method, organic materials are deposited at a desired location by closely attaching a thin metal mask (shadow mask) to a substrate.

Referring to FIG. 1, a conventional fine metal mask manufacturing method using plating is performed in the following manner. A substrate 4 [FIG. 1(a)] is prepared, and a plated resist 3 having a predetermined pattern is formed on the substrate 4.

Then, as illustrated in FIG. 1(b), plating is performed on the substrate 4 to form a metal thin plate 2. Then, the plated resist 3 is removed [FIG. 1(c)], and a mask 2 [or, metal thin plate 2] on which a pattern P is formed is separated from the substrate 4 [FIG. 1(d)].

Then, the cross-section of the metal thin plate 3 is processed into a trapezoidal shape through a laser trimming process.

In the conventional FMM manufacturing process as described above, the plated mask 2 is attached to the substrate 4 (mother plate) with a predetermined adhesive force. When separating the mask 2 from the substrate 4 by applying physical force, there is a problem in that wrinkles are formed in the mask 2 or the mask pattern P is deformed.

Additionally, the cross-section of all cells of an FMM is processed by adding the laser trimming process in order to prevent a shadow effect. This reduces mass productivity and causes an increase in manufacturing costs.

Moreover, when attempting to minimize the shadow effect by manufacturing the mask 2 with a thickness of equal to or less than 20 μm during plating, it is vulnerable to handling, which also reduces mass productivity and causes an increase in manufacturing costs.

### SUMMARY

Accordingly, the present disclosure has been made keeping in mind the above problems occurring in the related art, and an objective of the present disclosure is to provide an improved method for manufacturing a fine metal mask by improving a cross-sectional structure of a plated resist so that separation of a substrate and a plated layer (mask) can be easily achieved.

In order to accomplish the above objective, the present disclosure provides a method for manufacturing a fine metal mask, the method including: a) patterning a plated resist on a substrate; b) forming a metal plated layer on the substrate exposed through the patterned plated resist; c) removing the patterned plated resist after step b); and d) separating the metal plated layer and the substrate, in which in step a), a cross-section of the plated resist may be formed into a trapezoidal shape.

This may enable an FMM to be safely separated from the substrate without deformation.

Here, step a) may include: depositing the plated resist on the substrate; exposing the deposited plated resist using a photoresist; and patterning the plated resist by removing a portion other than an exposed portion exposed in the exposing of the plated resist. In the exposing of the plated resist, an exposed area of the plated resist may be increased in proportion to a depth thereof by causing light to be diffusely reflected on the substrate.

This may enable the cross-section of the plated resist to be formed into a trapezoidal shape.

Additionally, the light for exposure may be diffusely reflected by controlling a surface roughness of the substrate.

By controlling the surface roughness of the substrate to induce diffuse reflection of light, the light may be reflected laterally as well as vertically. This may enable the plated resist to be exposed laterally so that a position (pattern) where metal is to be plated gradually narrows toward a lower part thereof.

Additionally, in step d), the metal plated layer may be separated from the substrate using an etching process that selectively etches a seed layer formed on the substrate.

This may enable the metal plated layer (FMM) to be easily separated from the substrate with minimal damage.

Additionally, the seed layer may be made of a different metal from the metal plated layer.

This may enable the metal plated layer to be easily separated from the substrate using a selective etching method.

Additionally, the metal plated layer may include INVAR, and the seed layer may be Cu or Al.

This may enable the seed layer to be selectively etched without damaging the metal plated layer, thereby safely separating the metal plated layer from the substrate.

According to a method for manufacturing a fine metal mask according to the present disclosure, the amount of light during exposure of a plated resist can be increased by controlling the surface roughness of a substrate, thereby increasing the amount of light diffusely reflected on the substrate, and the cross-section of the plated resist can be formed into a trapezoidal shape by reducing the development time and pressure of the plated resist.

In this case, since the cross-section of a metal plated layer, i.e. an FMM, is plated into an inverted trapezoidal shape after plating, a laser trimming process does not need to be performed when manufacturing OLEDs, and a shadow effect caused by the FMM can be reduced.

Additionally, since the laser trimming process is omitted, manufacturing costs can be reduced and yield can be improved.

Additionally, the FMM can be separated from the substrate by a selective etching method, so the FMM can be safely separated without damage compared to the related art.

### DESCRIPTION OF DRAWINGS

FIG. 1 is a view illustrating a conventional fine metal mask manufacturing method.

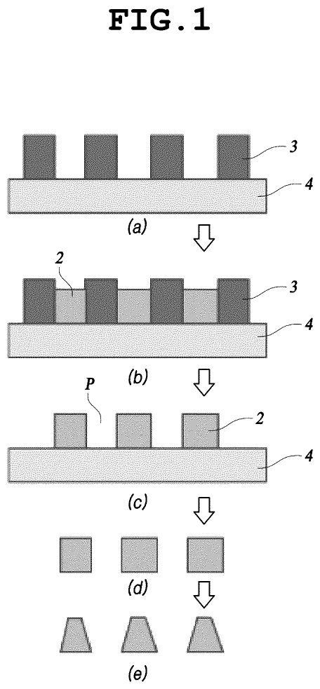

FIG. 2 is a flowchart illustrating a method for manufacturing a fine metal mask according to an embodiment of the present disclosure.

FIG. 3 is a configuration view illustrating the method for manufacturing the fine metal mask according to the embodiment of the present disclosure.

FIG. 4 is a view illustrating a process of patterning a plated resist.

FIG. 5 is a view illustrating a process of separating an FMM from a substrate using a selective etching process.

### DETAILED DESCRIPTION

The above and other objectives, features, and advantages of the present disclosure will be clearly understood from the more particular description of exemplary embodiments of the present disclosure. The present disclosure may, however, be embodied in different forms and should not be construed as limited to the embodiments set forth herein. Rather, these embodiments are provided so that this disclosure is thorough and complete and fully conveys the present disclosure to those skilled in the art.

In this specification, when an element is referred to as being on another element, it can be formed directly on the other element or intervening elements may be present therebetween. Further, in the drawings, the thicknesses of elements may be exaggerated for effective explanation of technical contents.

In this specification, although the terms first, second, etc. may be used to describe various elements, these elements should not be limited by these terms. These terms are only used to distinguish one element from another. The embodiments described and illustrated herein include their complementary embodiments.

Hereinbelow, a method for manufacturing a fine metal mask according to an embodiment will be described in detail with reference to the accompanying drawings.

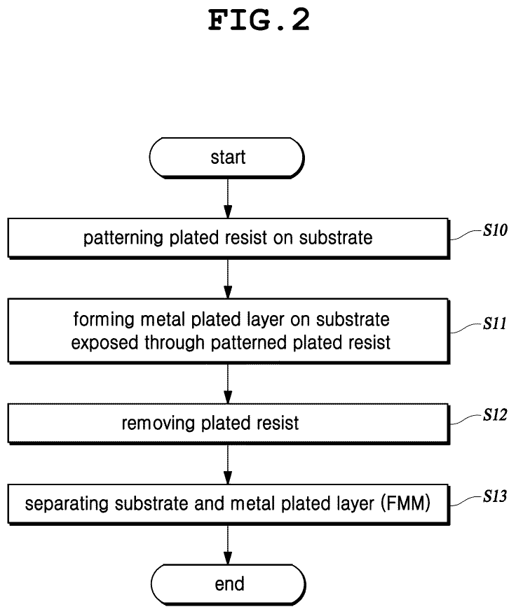

Referring to FIGS. 2 to 5, the method for manufacturing the fine metal mask according to the embodiment of the present disclosure includes: patterning a plated resist 20 on a substrate 10 (S10), forming a metal plated layer 30 on the substrate 10 exposed through the patterned plated resist 20′ (S11), removing the patterned plated resist 20′ after step S11 (S12), and separating the metal plated layer 30 and the substrate 10 (S13).

Step S10 is characterized in that the cross-section of the plated resist 20′ is formed into a trapezoidal shape.

Specifically, in step S10, the cross-section of the plated resist 20 may be patterned into an inverted trapezoidal shape using exposure and development processes.

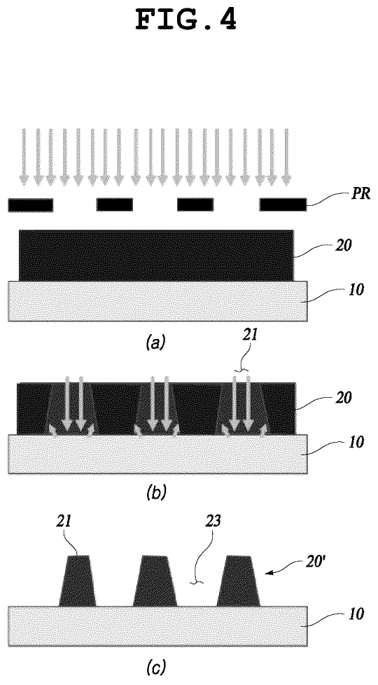

That is, as illustrated in FIG. 4, first, the plated resist 20 is deposited on the substrate 10.

Then, the deposited plated resist 20 is exposed using a photoresist PR. At this time, as illustrated in FIG. 4(b), an exposed area of an exposed portion 21 of the plated resist 20 may be increased in proportion to a depth thereof by causing light to be diffusely reflected on the substrate 10.

In order to increase the area of the exposed portion 21 as the depth thereof increases, considering that a light source used for exposure is parallel light, the light needs to be diffusely reflected on a surface of the substrate 10 so that it is reflected laterally. To this end, in the embodiment of the present disclosure, the roughness of the surface of the substrate 10 may be controlled to be increased. As a result, the light for exposure travels vertically (parallel light) and is reflected diffusely on the surface of the substrate 10, so the exposed portion 21 may gradually widen toward the substrate 10.

Then, the plated resist 20′ is patterned by removing a portion other than the exposed portion 21 exposed in the exposure process [FIG. 4(c)]. As a result, a pattern portion 23 of the patterned plated resist 20′, i.e., a position where metal is to be plated, may be formed to gradually narrow toward a lower part thereof.

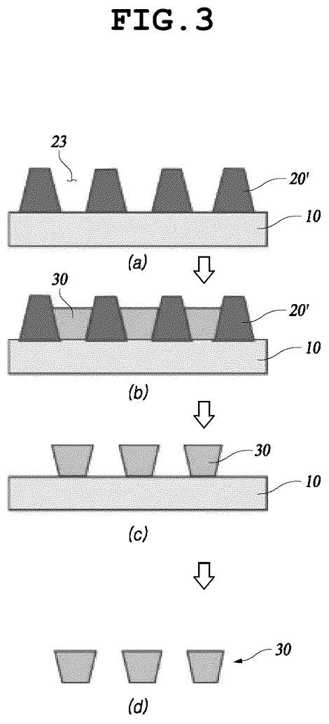

After patterning the plated resist 20′ as described above, a metal layer is deposited on top of it using an electroforming method to form the metal plated layer 30. As a result, as illustrated in FIG. 3(b), the metal plated layer 30 is formed by being deposited in the pattern portion 23 of the plated resist 20′ by plating, with a cross-section of an inverted trapezoidal shape.

Then, when the plated resist 20 is removed, as illustrated in FIG. 3(c), only the metal plated layer 30, i.e., the FMM, remains on the substrate 10.

Then, as FIG. 3(d), the metal plated layer 30 and the substrate 10 are separated from each other to obtain an FMM of a desired shape.

As described above, by plating the cross-section of the FMM 30 on the substrate 10 into an inverted trapezoidal shape during manufacturing of the FMM, a shadow effect caused by the FMM may be reduced without the need for performing a laser trimming process during OLED manufacturing. Therefore, since the laser trimming process is omitted, FMM manufacturing costs may be reduced and yield may be improved.

Additionally, when separating the FMM 30 from the substrate 10, it may be separated by a selective etching process rather than a physical removal method used in the related art.

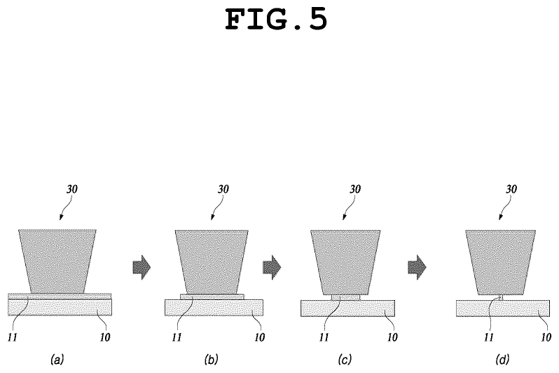

To this end, as illustrated in FIG. 5(a), it is preferable to form a seed layer 11 on the surface of the substrate 10 by depositing a different type of metal from the metal plated layer 30. Preferably, the metal plated layer 30 is made of an INVAR material by plating, and the seed layer 11 is made of a copper (Cu) or aluminum (Al) material.

At this time, it is preferable to use ammonia alkali etching in a sheet etching process. In this case, an etching ratio of Ni:Cu is 0.1:99.1. Therefore, as illustrated in FIG. 5(a) to 5(d), during the process of sequentially etching and removing the seed layer 11, the metal plated layer 30 is hardly etched and only the seed layer 11 is selectively etched and removed. This enables the metal plated layer 30, i.e., the FMM, to be safely separated by the etching process without applying physical force or impact.

Meanwhile, when manufacturing the FMM by forming the seed layer 11 on the substrate 10 as described above, the surface roughness of the seed layer 11 may be controlled to induce diffuse reflection of light for exposure, thereby manufacturing the FMM so that the cross-section thereof is an inverted trapezoid.

Those skilled in the art will appreciate that various alternatives, modifications, and equivalents are possible, without changing the spirit or essential features of the present disclosure. Therefore, preferred embodiments of the present disclosure have been described for illustrative purposes, and should not be construed as being restrictive. The scope of the present disclosure is defined by the accompanying claims rather than the description which is presented above. Moreover, the present disclosure is intended to cover not only the exemplary embodiments, but also various alternatives, modifications, equivalents and other embodiments that may be included within the spirit and scope of the present disclosure as defined by the appended claims.

What is claimed is:

1. A method for manufacturing a fine metal mask, the method comprising:
a) patterning a plated resist on a substrate;
b) forming a metal plated layer on the substrate exposed through the patterned plated resist;
c) removing the patterned plated resist after step b); and
d) separating the metal plated layer and the substrate,
wherein in step a), a cross-section of the plated resist is formed into a trapezoidal shape.

2. The method of claim 1, wherein step a) comprises:
depositing the plated resist on the substrate;
exposing the deposited plated resist using a photoresist; and
patterning the plated resist by removing a portion other than an exposed portion exposed in the exposing of the plated resist,
wherein in the exposing of the plated resist, an exposed area of the plated resist is increased in proportion to a depth thereof by causing light to be diffusely reflected on the substrate.

3. The method of claim 2, wherein the light for exposure is diffusely reflected by controlling a surface roughness of the substrate.

4. The method of claim 1, wherein in step d), the metal plated layer is separated from the substrate using an etching process that selectively etches a seed layer formed on the substrate.

5. The method of claim 4, wherein the seed layer is made of a different metal from the metal plated layer.

6. The method of claim 5, wherein the metal plated layer includes INVAR, and the seed layer is Cu or Al.
